(19) United States
(12) Patent Application Publication
(10) Pub. No.: US 2026/0262425 A1
(43) Pub. Date: Sep. 3, 2026

(54) DISPLAY PANEL AND DISPLAY DEVICE

(71) Applicants: Chengdu BOE Optoelectronics Technology Co., Ltd., Sichuan Province (CN); BOE Technology Group Co., Ltd., Beijing (CN)

(72) Inventors: Peng XU, Beijing (CN); Wei WANG, Beijing (CN); Yi ZHANG, Beijing (CN); Hongjun ZHOU, Beijing (CN)

(21) Appl. No.: 18/993,728

(22) PCT Filed: Mar. 13, 2024
(86) PCT No.: PCT/CN2024/081479

§ 371 Date: Jan. 13, 2025

(30) Foreign Application Priority Data
Apr. 28, 2023 (CN) 202310477857.1

(51) Int. Cl. H10K 59/80; H10K 59/40; H10K 102/00

(52) U.S. Cl. CPC H10K 59/879; H10K 59/40; H10K 2102/311

(57) ABSTRACT

A display panel includes: a base substrate including a bending area and a non-bending area; a first refractive index film layer on the base substrate; and a second refractive index film layer on a side of the first refractive index film layer away from the base substrate. The refractive index of the second refractive index film layer is greater than that of the first refractive index film layer. The orthographic projection of the second refractive index film layer on the base substrate does not overlap with the bending area. The orthographic projection of the second refractive index film layer on the base substrate is provided with a first boundary close to the bending area. The bending area is provided with a second boundary close to the second refractive index film layer. The first distance between the first boundary and the second boundary is greater than 0.

### CROSS-REFERENCE TO RELATED APPLICATIONS

This application is a national phase entry under 35 U.S.C. § 371 of International Application No. PCT/CN2024/081479, filed on Mar. 13, 2024, which claims priority to Chinese Patent Application No. 202310477857.1, filed with the China National Intellectual Property Administration on Apr. 28, 2023 and entitled “Display Panel and Display Device”, the entire contents of which are incorporated herein by reference.

### TECHNICAL FIELD

The present disclosure relates to the field of display technology, and in particular to a display panel and a display device.

### BACKGROUND

With the development of display technology, consumers' demands for display panels are becoming more diversified and personalized. Display panels have advantages such as bendability and portability, and are favored by consumers. However, when the display panel is bent, water vapor may enter the bending area to reach the signal line, causing corrosion of the signal line and causing a black screen on the display panel.

### SUMMARY

Embodiments of the present disclosure provide a display panel, including:
a substrate including: a bending area and a non-bending area; the non-bending area including a display area having a plurality of sub-pixels;
a first refractive index film layer on the base substrate, the first refractive index film layer being disposed in the display area, and the first refractive index film layer being provided with a plurality of openings, and the plurality of openings being disposed correspondingly to the plurality of sub-pixels;
a second refractive index film layer on a side of the first refractive index film layer away from the base substrate, the second refractive index film layer covering the first refractive index film layer in the display area and filling the plurality of openings.

A refractive index of the second refractive index film layer is greater than a refractive index of the first refractive index film layer. An orthographic projection of the second refractive index film layer on the base substrate does not overlap with the bending area. The orthographic projection of the second refractive index film layer on the base substrate has a first boundary close to the bending area. The bending area has a second boundary close to the second refractive index film layer. A first distance between the first boundary and the second boundary is greater than 0.

In some possible implementations, the non-bending area includes a first non-bending area and a second non-bending area. The first non-bending area and the second non-bending area are arranged on both sides of the bending area.

The first non-bending area includes the display area. The second refractive index film layer is disposed in the first non-bending area. The orthographic projection of the second refractive index film layer on the base substrate covers the display area.

In some possible implementations, the first boundary of the orthographic projection of the second refractive index film layer on the base substrate is aligned with a boundary of the display area close to the bending area.

In some possible implementations, the first non-bending area further includes: a non-display area disposed between the display area and the bending area.

The orthographic projection of the second refractive index film layer on the base substrate also covers a portion of the non-display area.

In some possible implementations, the first non-bending area further includes: at least two blocking dams surrounding the display area.

The orthographic projection of the second refractive index film layer on the base substrate covers the orthographic projections of all the blocking dams on the base substrate.

Alternatively, the orthographic projection of the second refractive index film layer on the base substrate does not overlap with a side edge of at least one blocking dam close to the bending area. The orthographic projection of the second refractive index film layer on the base substrate also covers the orthographic projections of the remaining side edges of all blocking dams on the base substrate.

In some possible implementations, the at least two blocking dams include: a first blocking dam and a second blocking dam. The first blocking dam is disposed to surround the display area, and the second blocking dam is annularly disposed at the periphery of the first blocking dam.

The orthographic projection of the second refractive index film layer on the base substrate does not overlap with the orthographic projection of the side edge of the second blocking dam close to the bending area on the base substrate. The orthographic projection of the second refractive index film layer on the base substrate also covers the orthographic projection of the first blocking dam and the remaining side edges of the second blocking dam on the base substrate.

In some possible implementations, the non-display area is further provided with the first refractive index film layer.

In the non-display area, the orthographic projection of the first refractive index film layer on the base substrate covers the orthographic projection of the second refractive index film layer on the base substrate.

In some possible implementations, the display panel further includes: a touch insulating layer disposed between the first refractive index film layer and the base substrate. The touch insulating layer is disposed in the first non-bending area and the second non-bending area.

The orthographic projection of the touch insulating layer in the first non-bending area on the base substrate has a third boundary close to the bending area. A second distance is between the third boundary and the second boundary. The second distance is not greater than the first distance.

In some possible implementations, the first non-bending area further includes: at least two blocking dams surrounding the display area.

The orthographic projection of the touch insulating layer in the first non-bending area on the base substrate covers the orthographic projections of all the blocking dams on the base substrate.

In some possible embodiments, the orthographic projection of the touch insulating layer in the second non-bending area on the base substrate has a fourth boundary close to the bending area. The bending area has a fifth boundary close to the second non-bending area. A third distance is between the fourth boundary and the fifth boundary. The third distance is not greater than the first distance.

In some possible implementations, the third distance is equal to the second distance.

In some possible implementations, in the non-display area, the orthographic projection of the first refractive index film layer on the base substrate covers the orthographic projection of the touch insulating layer on the base substrate.

In some possible implementations, the orthographic projection of the first refractive index film layer on the base substrate also covers the non-display area and a portion of the bending area.

In some possible implementations, the orthographic projection of the first refractive index film layer on the base substrate is disposed in the non-bending area.

In some possible implementations, the orthographic projection of the first refractive index film layer in the first non-bending area on the base substrate has a sixth boundary close to the bending area. There is a fourth distance between the sixth boundary and the third boundary. The fourth distance is not less than 10 μm.

In some possible embodiments, the orthographic projection of the first refractive index film layer in the second non-bending area on the base substrate has a seventh boundary close to the bending area. There is a fifth distance between the seventh boundary and the fourth boundary. The fifth distance is not less than 10 μm.

In some possible implementations, the fourth distance is equal to the fifth distance.

In some possible implementations, the display panel further includes: a plurality of signal lines. The plurality of signal lines include: a plurality of data lines and a low voltage signal line.

In the bending area, the orthographic projection of the region where the low voltage signal line is located on the base substrate is arranged between the orthographic projection of the region where the plurality of data lines are located on the base substrate and an edge of the base substrate.

In some possible implementations, the plurality of signal lines further include: an initialization signal line, a plurality of clock signal lines, and a high voltage signal line.

In the bending area, the orthographic projection of the region where the low voltage signal line is located on the substrate is arranged between orthographic projections of regions where two adjacent signal lines are located on the base substrate, including the orthographic projection of the region where the multiple data lines are located on the base substrate, the orthographic projection of the region where the initialization signal line is located on the base substrate, the orthographic projection of the region where the multiple clock signal lines are located on the base substrate, and the orthographic projection of the region where the high voltage signal line is located on the base substrate.

In some possible implementations, in the bending area, the plurality of data lines and the low voltage signal line are arranged in a first conductive layer. The initialization signal line, the plurality of clock signal lines and the high voltage signal line are arranged in a second conductive layer.

The first conductive layer is disposed between the second conductive layer and the base substrate. An insulating layer is disposed between the first conductive layer and the second conductive layer.

In some possible implementations, in the bending area, the plurality of data lines are disposed in a first conductive layer. The low voltage signal line, the initialization signal line, the plurality of clock signal lines, and the high voltage signal line are disposed in a second conductive layer.

The first conductive layer is disposed between the second conductive layer and the base substrate. An insulating layer is disposed between the first conductive layer and the second conductive layer.

In some possible implementations, in the bending area, the low voltage signal line includes a first low voltage signal line and a second low voltage signal line connected to each other.

The plurality of data lines and the first low voltage signal line are arranged in a first conductive layer. The second low voltage signal line, the initialization signal line, the plurality of clock signal lines and the high voltage signal line are arranged in a second conductive layer.

The first conductive layer is disposed between the second conductive layer and the base substrate. An insulating layer is disposed between the first conductive layer and the second conductive layer.

In some possible implementations, the thickness of the layer where the low voltage signal line is located is A*110% to A*130%, where A represents a set thickness.

In some possible implementations, the portion of the low voltage signal line in the bending area includes: a plurality of low voltage sub-signal lines arranged at intervals from each other.

One ends of the plurality of low voltage sub-signal lines are connected to the low voltage signal line in the first non-bending area, and the other ends of the plurality of low voltage sub-signal lines are connected to the low voltage signal line in the second non-bending area.

In some possible implementations, the display panel further includes: at least one dummy signal line disposed between the plurality of signal lines and an edge of the base substrate.

In some possible implementations, the dummy signal line and the low voltage signal line are provided on the same layer.

Embodiments of the present disclosure further provide a display panel, which includes:
a base substrate including: a bending area and a first non-bending area; the first non-bending area including a display area having a plurality of sub-pixels;
a first refractive index film layer on the base substrate, the first refractive index film layer being disposed in the display area, the first refractive index film layer being provided with a plurality of openings, and the plurality of openings being disposed correspondingly to the plurality of sub-pixels;
a second refractive index film layer on a side of the first refractive index film layer away from the base substrate, the second refractive index film layer covering the first refractive index film layer in the display area and filling the plurality of openings; the refractive index of the second refractive index film layer being greater than the refractive index of the first refractive index film layer; and the orthographic projection of the second refractive index film layer on the base substrate not overlapping with the bending area;
a touch insulating layer between the first refractive index film layer and the base substrate.

The orthographic projection of the second refractive index film layer on the base substrate has a first boundary close to the bending area. An orthographic projection of the touch insulating layer in the first non-bending area on the base substrate has a third boundary close to the bending area. An orthographic projection of the first refractive index film layer in the first non-bending area on the base substrate has a sixth boundary close to the bending area. The third boundary is on a side of the first boundary away from the display area. The sixth boundary is on a side of the third boundary away from the display area.

In some possible implementations, the bending area has a second boundary close to the second refractive index film layer, and a first distance between the first boundary and the second boundary is greater than 0.

In some possible implementations, there is a second distance between the third boundary and the second boundary, and the second distance is not greater than the first distance.

Embodiments of the present disclosure further provide a display device, including the above-mentioned display panel.

### BRIEF DESCRIPTION OF DRAWINGS

FIG. 1 is a schematic diagram of some structures of a display panel in an embodiment of the present disclosure.

FIG. 2 is a schematic diagram of some other structures of a display panel in an embodiment of the present disclosure.

FIG. 3 is a schematic diagram of some other structures of a display panel in an embodiment of the present disclosure.

FIG. 4 is a schematic diagram of some other structures of a display panel in an embodiment of the present disclosure.

FIG. 5 is a schematic diagram of some other structures of a display panel in an embodiment of the present disclosure.

FIG. 6 is a schematic diagram of some other structures of a display panel in an embodiment of the present disclosure.

FIG. 7 is a schematic diagram of some other structures of a display panel in an embodiment of the present disclosure.

FIG. 8 is a schematic diagram of some other structures of a display panel in an embodiment of the present disclosure.

FIG. 9 is a schematic diagram of some other structures of a display panel in an embodiment of the present disclosure.

FIG. 10 is a schematic diagram of some other structures of a display panel in an embodiment of the present disclosure.

FIG. 11 is a schematic diagram of some other structures of a display panel in an embodiment of the present disclosure.

FIG. 12 is a schematic diagram of some other structures of a display panel in an embodiment of the present disclosure.

FIG. 13A is a schematic diagram of some other structures of a display panel in an embodiment of the present disclosure.

FIG. 13B is a schematic diagram of some other structures of a display panel in an embodiment of the present disclosure.

FIG. 14A is a schematic diagram of some other structures of a display panel in an embodiment of the present disclosure.

FIG. 14B is a schematic diagram of some other structures of a display panel in an embodiment of the present disclosure.

FIG. 15 is a schematic diagram of some other structures of a display panel in an embodiment of the present disclosure.

FIG. 16 is a schematic diagram of some other structures of a display panel in an embodiment of the present disclosure.

### DETAILED DESCRIPTION

In order to make the purpose, technical solution and advantages of the embodiments of the present disclosure more clear, the technical solution of the embodiments of the present disclosure will be clearly and completely described below in conjunction with the drawings of the embodiments of the present disclosure. Obviously, the described embodiments are only part of the embodiments of the present disclosure, rather than all the embodiments. Furthermore, the embodiments in the present disclosure and the features in the embodiments may be combined with each other without conflict. Based on the described embodiments of the present disclosure, all other embodiments obtained by those of ordinary skill in the art without creative work are within the scope of protection of the present disclosure.

Unless otherwise defined, technical or scientific terms used in the present disclosure should have the common meanings understood by a person having ordinary skills in the field to which the present disclosure belongs. The terms “first”, “second” and the like used in the present disclosure do not indicate any order, quantity or importance, but are only used to distinguish different components. The words “include” or “comprise” and the like mean that the elements or objects preceding the word include the elements or objects listed after the word and their equivalents, but do not exclude other elements or objects. The words “connect” or “connected” and the like are not limited to physical or mechanical connections, but may include electrical connections, whether direct or indirect.

It should be noted that the size and shape of each figure in the accompanying drawings do not reflect the actual proportion, and the purpose is only to illustrate the contents of the present disclosure. And the same or similar reference numerals throughout represent the same or similar elements or elements having the same or similar functions.

In embodiments of the present disclosure, the display device includes a display panel. The display panel includes a display area. The display area has a plurality of pixel units. Each pixel unit includes a plurality of sub-pixels. Each sub-pixel may include a light emitting device and a pixel driving circuit for driving the light emitting device to emit light. The light emitting device includes an anode, a light emitting functional layer and a cathode which are stacked. Furthermore, the light emitting device may include at least one of an organic light emitting diode (OLED), a quantum dot light emitting diode (QLED), a Micro LED or a Mini LED. Moreover, the pixel driving circuit may generally include a plurality of transistors such as a driving transistor and a switching transistor, and a storage capacitor. The structure and working principle of the pixel driving circuit may be the same as those in the prior art, and will not be elaborated herein.

The display device in embodiments of the present disclosure may be a flexible display device. Optionally, the display panel may be a flexible display panel. Of course, the display device in embodiments of the present disclosure may also be a display device in other forms, and the display panel may also be a display panel in other forms, which are not limited here.

Exemplarily, each pixel unit includes a red sub-pixel, a green sub-pixel and a blue sub-pixel. The red sub-pixel includes a light emitting device that displays red, the green sub-pixel includes a light emitting device that displays green, and the blue sub-pixel includes a light emitting device that displays blue.

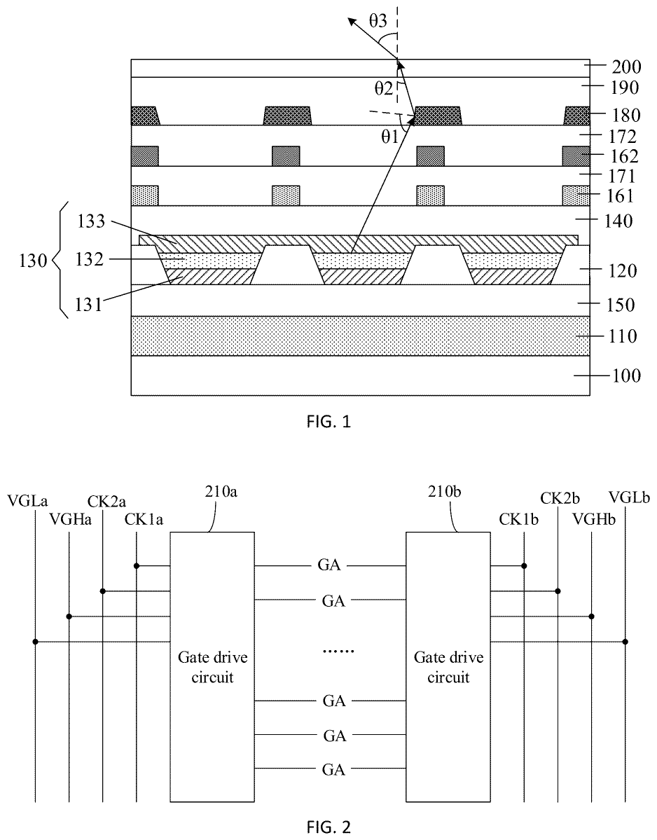

For example, as shown in FIG. 1, the display panel may include: a base substrate 100, a thin film transistor array layer 110 disposed on the base substrate 100, a planarization layer 150 disposed on a side of the thin film transistor array layer 110 away from the base substrate 100, a pixel defining layer 120 disposed on a side of the planarization layer 150 away from the base substrate 100, a light emitting device 130 disposed in an opening of the pixel defining layer 120, a thin film encapsulation layer 140 disposed on a side of the light emitting device 130 away from the base substrate 100, a first touch electrode film layer 161 disposed on a side of the thin film encapsulation layer 140 away from the base substrate 100, a first touch insulating layer 171 disposed on a side of the first touch electrode film layer 161 away from the base substrate 100, a second touch electrode film layer 162 disposed on a side of the first touch insulating layer 171 away from the base substrate 100, a second touch insulating layer 172 disposed on a side of the second touch electrode film layer 162 away from the base substrate 100, a first refractive index film layer 180 disposed on a side of the second touch insulating layer 172 away from the base substrate 100, a second refractive index film layer 190 disposed on a side of the first refractive index film layer 180 away from the base substrate 100, and a cover plate 200 disposed on a side of the second refractive index film layer 190 away from the base substrate 100.

Exemplarily, the first touch electrode film layer 161 and the second touch electrode film layer 162 are respectively provided with touch electrodes, so that a capacitive touch function can be realized through mutual capacitance technology. Furthermore, the orthographic projection of the touch electrodes on the base substrate does not overlap with the orthographic projection of the opening area of the sub-pixels on the base substrate, thereby avoiding affecting the display effect. Furthermore, touch electrodes in one of the first touch electrode film layer 161 and the second touch electrode film layer 162 may be connected through a via hole penetrating the first touch insulating layer 171.

Exemplarily, a plurality of signal lines are arranged on the base substrate 100. The plurality of signal lines include a plurality of gate lines, a plurality of data lines, an initialization signal line and a power signal line. For example, pixel driving circuits in a row of sub-pixels are connected to one gate line. Pixel driving circuits in a column of sub-pixels are connected to one data line. Pixel driving circuits in a column of sub-pixels are connected to one initialization signal line. Pixel driving circuits in a column of sub-pixels are connected to one power signal line. In this way, corresponding signals can be input to the pixel driving circuits through these signal lines to control the pixel driving circuits to drive the light-emitting devices to emit light.

Exemplarily, a gate driving circuit(s) connected to a plurality of gate lines is/are arranged on the base substrate. A gate scanning signal is input to the gate line through the gate driving circuit to control the transistor in the pixel driving circuit to be turned on or off. Optionally, the gate driving circuit includes a transistor or a capacitor. The structure and working principle of the gate driving circuit may be the same as those in the prior art, which will not be described in detail here.

Exemplarily, a pixel driving circuit, a gate driving circuit and a signal line are formed in the thin film transistor array layer. Exemplarily, the thin film transistor array layer may include: a semiconductor layer, a gate conductive layer, a capacitor electrode layer, a first conductive layer, and a second conductive layer. Furthermore, an insulating layer is arranged between every two adjacent conductive film layers among the semiconductor layer, the gate conductive layer, the capacitor electrode layer, the first conductive layer and the second conductive layer. Furthermore, two film layers that need to be coupled are coupled to each other through via holes penetrating the insulating layer.

Illustratively, the semiconductor layer includes the active layer in the above-mentioned transistors. The semiconductor layer may be formed by patterning semiconductor materials. The semiconductor layer is used to prepare the active layer of the transistors. By way of example, the semiconductor layer may be made of amorphous silicon, polycrystalline silicon, oxide semiconductor materials, or the like. It should be noted that the source region and the drain region may be conductive regions formed by doping with n-type impurities or p-type impurities.

Exemplarily, the gate conductive layer includes the gate and gate line in the above-mentioned transistors. The gate of a transistor is reused as an electrode of the capacitor.

Exemplarily, the capacitor electrode layer includes another electrode of the capacitor. Two electrodes with facing areas form the capacitor.

Exemplarily, the first conductive layer includes the data lines.

Exemplarily, the second conductive layer includes the above-mentioned initialization signal line and power signal line.

Exemplarily, as shown in FIG. 1, the light emitting device 130 includes an anode 131, a light emitting functional layer 132, and a cathode 133 which are stacked.

For example, the thin film encapsulation layer may include a first inorganic encapsulation layer (e.g., a SiON layer), an organic encapsulation layer (e.g., an acrylic layer), and a second inorganic encapsulation layer (e.g., a SiN layer) which are stacked.

Exemplarily, in combination with FIG. 1, a first refractive index film layer 180 and a second refractive index film layer 190 are arranged in the display area. The first refractive index film layer 180 has a plurality of openings, and the plurality of openings are arranged corresponding to the light emitting areas of a plurality of sub-pixels. The second refractive index film layer 190 covers the first refractive index film layer 180 and fills the openings of the first refractive index film layer 180. The refractive index of the second refractive index film layer is greater than the refractive index of the first refractive index film layer, which can improve the light exiting angle of the light emitting device and increase the light brightness. As shown in FIG. 1, the refractive index of the first refractive index film layer 180 is, for example, 1.47. The refractive index of the second refractive index film layer 190 is, for example, 1.7. The refractive index of the cover plate 200 is, for example, 1.5. The refractive index of the air is, for example, 1. Since the first refractive index film layer 180 is provided with openings corresponding to sub-pixels, the second refractive index film layer 190 covers the first refractive index film layer 180 and fills the openings of the first refractive index film layer 180, the light emitted laterally from the sub-pixel is totally reflected at the boundary between the first refractive index film layer 180 and the second refractive index film layer 190, so that the light emitted in a lateral direction can be exited in the forward direction, thereby improving the luminous efficiency and increasing the light brightness.

The present disclosure does not limit the materials of the first refractive index film layer and the second refractive index film layer. Exemplarily, the first refractive index film layer may adopt a low refractive index optical adhesive, and the second refractive index film layer may adopt a high refractive index optical adhesive.

In implementations, the display panel may drive the gate lines in a unilateral manner, that is, a gate driving circuit is disposed only on one side of the gate lines. Alternatively, as shown in FIG. 2, the display panel may also drive the gate lines in a double-sided manner, that is, gate driving circuits 210a and 210b are respectively disposed on both sides of the gate lines GAs.

Usually, it is necessary to input corresponding signals to the gate driving circuits 210a and 210b to control the gate driving circuits to input gate scanning signals to the gate lines. The plurality of signal lines further include: a plurality of clock signal lines, high voltage signal lines and low voltage signal lines connected to the gate driving circuits. For example, as shown in FIG. 2, clock signal lines CK1a and CK2a, a high voltage signal line VGHa and a low voltage signal line VGLa connected to the gate drive circuit 210a can be set, and clock signal lines CK1b and CK2b, a high voltage signal line VGHb and a low voltage signal line VGLb connected to the gate drive circuit 210b can be set. In this way, a clock signal is transmitted to the gate drive circuit through the clock signal line, a high voltage signal is input to the gate drive circuit through the high voltage signal line, and a low voltage signal is input to the gate drive circuit through the low voltage signal line, thereby controlling the gate drive circuit to input a gate scanning signal to the gate line.

The display panel includes a bending area WB and a non-bending area. In the existing design, the low voltage signal line is usually at the outermost side of the bending area WB, close to the edge of the base substrate. Furthermore, in order to cover the first refractive index film layer, the second refractive index film layer is designed to be in the bending area WB. Since the material of the second refractive index film layer is relatively brittle, cracks will appear after bending, causing water vapor to enter through the cracks. However, the voltage (negative value) transmitted on the low voltage signal line is usually low, resulting in a large voltage difference between the low voltage signal line and the adjacent signal line. When running under the reliability double 85 (for example, a reliability test of 85% humidity and 85% temperature), the low voltage signal line is corroded and broken, resulting in a black screen.

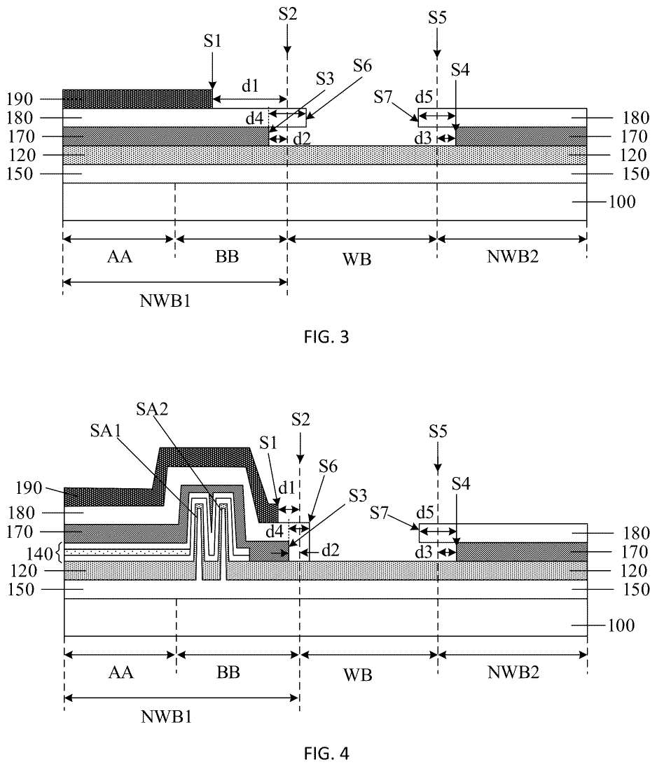

Based on this, as shown in FIG. 3, in the display panel provided by embodiments of the present disclosure, the orthographic projection of the second refractive index film layer 190 on the base substrate 100 does not overlap with the bending area WB. The orthographic projection of the second refractive index film layer 190 on the base substrate 100 has a first boundary S1 close to the bending area WB. The bending area WB has a second boundary S2 close to the second refractive index film layer 190. A first distance d1 between the first boundary S1 and the second boundary S2 is greater than 0. In this way, the first boundary S1 of the second refractive index film layer 190 is moved to a first distance d1 from the second boundary S2, so as to prevent the first boundary S1 from falling into the bending area WB, avoid cracks in the second refractive index film layer 190 when bending, reduce corrosion and breakage of the low voltage signal line, and avoid a black screen.

In some embodiments of the present disclosure, as shown in FIG. 3 to FIG. 7, the non-bending area includes a first non-bending area NWB1 and a second non-bending area NWB2. The first non-bending area NWB1 and the second non-bending area NWB2 are disposed on both sides of the bending area WB. The first non-bending area NWB1 includes the display area AA. The second non-bending area NWB2 includes the bonding area. The second refractive index film layer 190 is disposed in the first non-bending area NWB1. The second refractive index film layer 190 is not disposed in the second non-bending area NWB2. Furthermore, the orthographic projection of the second refractive index film layer 190 on the base substrate 100 covers the display area AA. The orthographic projection of the first refractive index film layer 180 on the base substrate 100 has an overlapping area with the display area AA, thereby improving the light exiting angle of the light emitting device and increasing the light brightness.

In some embodiments of the present disclosure, as shown in FIG. 3, the first non-bending area NWB1 further includes: a non-display area BB disposed between the display area AA and the bending area WB. The orthographic projection of the second refractive index film layer 190 on the base substrate 100 also covers a portion of the non-display area BB. Exemplarily, the present disclosure does not limit the first distance d1, for example, d1≥105 μm. Optionally, d1 can be selected from 105 μm, 107 μm, 109 μm, 110 μm, 113 μm, etc.

It should be noted that non-display areas BB are also arranged at the other boundaries of the display area AA. Signal lines and gate driving circuits are arranged in these non-display areas BB. The orthographic projection of the second refractive index film layer 190 on the base substrate 100 also covers the non-display areas BB at the other boundaries of the display area AA. The orthographic projection of the first refractive index film layer 180 on the base substrate 100 also covers the non-display areas BB at the other boundaries of the display area AA.

In order to block the flow of the organic encapsulation layer in the thin film encapsulation layer and improve the encapsulation effect, a blocking dam is arranged around the display area AA. In some embodiments of the present disclosure, as shown in FIG. 4 to FIG. 6, the first non-bending area NWB1 further includes: at least two blocking dams (such as SA1 and SA2) surrounding the display area AA. The blocking dams (such as SA1 and SA2) are arranged in the non-display area BB. The number of blocking dams may be two, three, four or more, which is not limited here. FIGS. 4 to 6 are described by taking two blocking dams as an example. Two blocking dams are provided: a first blocking dam SA1 and a second blocking dam SA2. The first blocking dam SA1 is provided to surround the display area AA, and the second blocking dam SA2 is provided in an annular manner on the periphery of the first blocking dam SA1.

In some examples, as shown in FIGS. 4 to 6, the first blocking dam SA1 and the second blocking dam SA2 can be prepared while preparing the planarization layer 150 and the pixel defining layer 120, so that the first blocking dam SA1 and the second blocking dam SA2 are formed using the stacked structure of the pixel defining layer 120 and the planarization layer 150, and the process flow is reduced.

In some other examples, the first blocking dam and the second blocking dam may be prepared while preparing the pixel defining layer, so that the first blocking dam, the second blocking dam and the pixel defining layer are an integrated structure. The process flow is reduced. Alternatively, the first blocking dam and the second blocking dam may be prepared while preparing the planarization layer, so that the first blocking dam, the second blocking dam and the planarization layer are an integrated structure. The process flow is reduced.

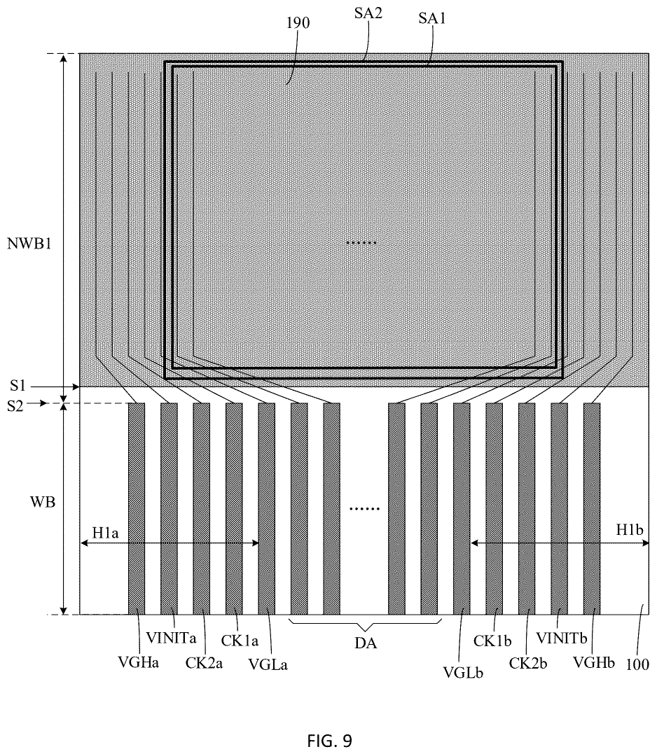

In some embodiments of the present disclosure, the orthographic projection of the second refractive index film layer 190 on the base substrate 100 can cover the orthographic projections of all blocking dams on the base substrate 100, so that the second refractive index film layer 190 can completely cover the display area AA. Furthermore, the orthographic projection of the first refractive index film layer 180 on the base substrate 100 can cover the orthographic projections of all the blocking dams on the base substrate 100, so that the first refractive index film layer 180 can completely cover the display area AA. For example, as shown in FIGS. 4 and 9, the orthographic projections of the second refractive index film layer 190 and the first refractive index film layer 180 on the base substrate 100 cover the orthographic projections of the first blocking dam and the second blocking dam on the base substrate 100.

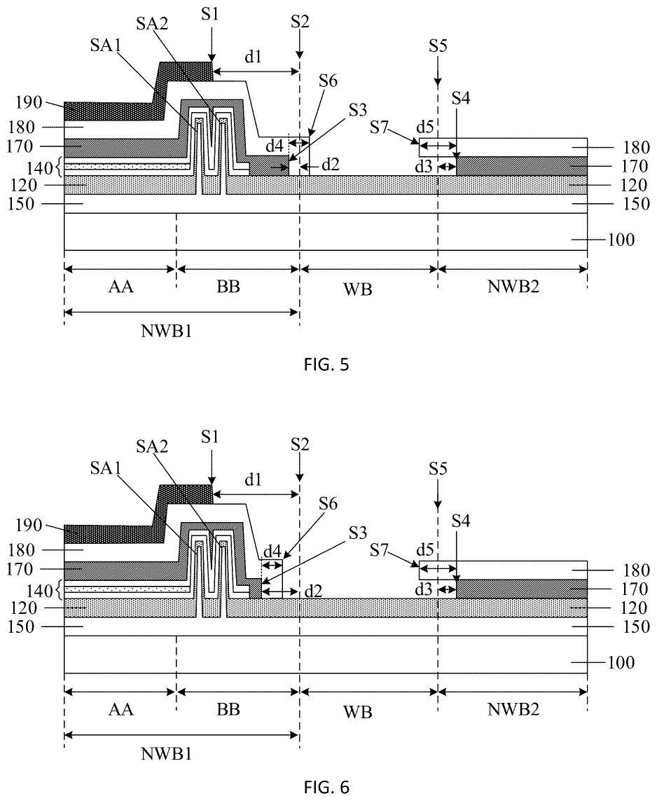

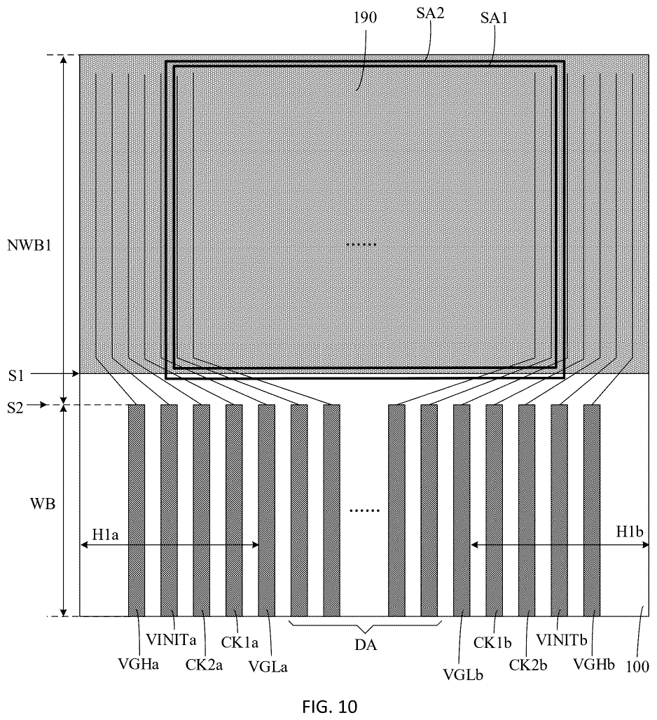

In some embodiments of the present disclosure, the orthographic projection of the second refractive index film layer 190 on the base substrate 100 may not overlap with a side edge of at least one blocking dam close to the bending area WB. The orthographic projection of the second refractive index film layer 190 on the base substrate 100 covers the orthographic projections of the remaining side edges of all blocking dams on the base substrate 100. For example, as shown in FIGS. 5, 6 and 10, the orthographic projection of the second refractive index film layer 190 on the base substrate 100 does not overlap with the orthographic projection of the side edge of the second blocking dam SA2 near the bending area WB on the base substrate 100, and the orthographic projection of the second refractive index film layer 190 on the base substrate 100 also covers the orthographic projections of the first blocking dam SA1 and the remaining side edges of the second blocking dam SA2 on the base substrate 100. Based on this, d1≥450 μm can be made. Optionally, d1 can be selected from 450 μm, 455 μm, 458 μm, 460 μm, 465 μm, etc.

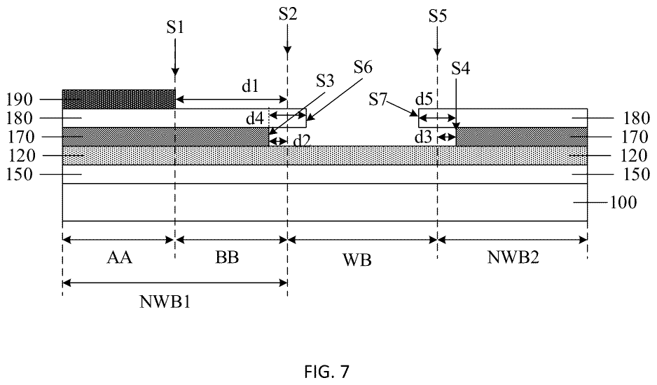

In some embodiments of the present disclosure, as shown in FIG. 7, the first boundary S1 of the orthographic projection of the second refractive index film layer 190 on the base substrate 100 can be aligned with the boundary of the display area AA near the bending area WB, so that the second refractive index film layer 190 can completely cover the display area AA. Based on this, d1≥600 μm can be made. Optionally, d1 can be selected from 600 μm, 602 μm, 605 μm, 610 μm, 613 μm, etc.

It should be noted that in actual processes, due to limitations of process conditions or other factors, the above-mentioned boundary alignment cannot be completely aligned and there may be some deviations. Therefore, as long as the above-mentioned boundary alignment roughly meets the above-mentioned conditions, it belongs to the protection scope of the present disclosure. For example, the boundary alignment may be an alignment allowed within an allowable error range.

In some embodiments of the present disclosure, as shown in FIGS. 3 to 7, in the non-display area BB, the orthographic projection of the first refractive index film layer 180 on the base substrate 100 covers the orthographic projection of the second refractive index film layer 190 on the base substrate 100.

In some embodiments of the present disclosure, as shown in FIG. 3 to FIG. 7, the display panel further includes: a touch insulating layer 170 disposed between the first refractive index film layer 180 and the base substrate 100. Exemplarily, the touch insulating layer 170 includes a first touch insulating layer and/or a second touch insulating layer. The touch insulating layer 170 is disposed in the first non-bending area NWB1 and the second non-bending area NWB2. The orthographic projection of the touch insulating layer 170 in the first non-bending area NWB1 on the base substrate 100 has a third boundary S3 close to the bending area WB. The third boundary S3 can be set on the side of the first boundary S1 away from the display area AA. Exemplarily, there is a second distance d2 between the third boundary S3 and the second boundary S2. In this way, the third boundary S3 of the touch insulating layer 170 is moved to a second distance d2 from the second boundary S2, so as to prevent the third boundary S3 from falling into the bending area WB, prevent cracks from appearing in the touch insulating layer 170, reduce the corrosion and disconnection of the low voltage signal line, and avoid a black screen.

Exemplarily, by setting the second distance d2 to be smaller than the first distance d1, the third boundary S3 of the touch insulating layer 170 can be closer to the bending area WB. Alternatively, the second distance d2 may be set equal to the first distance d1, which is not limited here.

This application does not limit the specific value of d2. Exemplarily, d2≥5 μm may be made. For example, d2 can be selected from 5 μm, 6 μm, 8 μm, 10 μm, and 15 μm.

Exemplarily, the orthographic projection of the touch insulating layer 170 on the base substrate 100 covers the display area AA. Alternatively, the orthographic projection of the touch insulating layer 170 on the base substrate 100 covers the display area AA and a portion of the non-display area BB in the first non-bending area NWB1.

Exemplarily, the orthographic projection of the touch insulating layer 170 on the base substrate 100 covers the second non-bending area NWB2. Alternatively, the orthographic projection of the touch insulating layer 170 on the base substrate 100 covers a portion of the second non-bending area NWB2.

For example, as shown in FIG. 4 to FIG. 6, the orthographic projection of the touch insulating layer 170 in the first non-bending area NWB1 on the base substrate 100 may cover the orthographic projections of all the blocking dams on the base substrate 100. In this way, the touch insulating layer 170 in the first non-bending area NWB1 can completely cover the display area AA.

In some embodiments of the present disclosure, as shown in FIGS. 3 to 7, the orthographic projection of the touch insulating layer 170 in the second non-bending area NWB2 on the base substrate 100 has a fourth boundary S4 close to the bending area WB. The bending area WB has a fifth boundary S5 close to the second non-bending area NWB2. A third distance d3 is between the fourth boundary S4 and the fifth boundary S5. In this way, the fourth boundary S4 of the touch insulating layer 170 is moved to a third distance d3 from the fifth boundary S5, so as to prevent the fourth boundary S4 from falling into the bending area WB, prevent cracks from appearing in the touch insulating layer 170, reduce the corrosion and disconnection of the low voltage signal line, and avoid a black screen.

Exemplarily, by setting the third distance d3 to be smaller than the first distance d1, the fourth boundary S4 of the touch insulating layer 170 can be closer to the bending area WB. Alternatively, the third distance d3 may be set equal to the first distance d1, which is not limited here.

Exemplarily, the third distance d3 may be set to be the same as the second distance d2, so that the touch insulating layer 170 on both sides of the bending area WB is at the same distance from the bending area WB, thereby achieving a symmetrical arrangement.

It should be noted that in actual processes, due to limitations of process conditions or other factors, the above-mentioned same may not be completely the same and there may be some deviations. Therefore, as long as the above-mentioned same roughly meet the above-mentioned conditions, it falls within the protection scope of the present disclosure. For example, the above-mentioned same may be the same allowed within the allowable error range.

In some embodiments of the present disclosure, as shown in FIG. 3 to FIG. 7, the orthographic projection of the touch insulating layer 170 on the base substrate 100 covers the orthographic projection of the second refractive index film layer 190 on the base substrate 100.

In some embodiments of the present disclosure, as shown in FIG. 3 to FIG. 7, in the non-display area BB, the orthographic projection of the first refractive index film layer 180 on the base substrate 100 covers the orthographic projection of the touch insulating layer 170 on the base substrate 100. In this way, the first refractive index film layer 180 in the non-display area BB can surround the touch insulating layer 170 to protect the touch insulating layer 170. Furthermore, in this way, the first refractive index film layer 180 is disposed in both the first non-bending area NWB1 and the second non-bending area NWB2.

In some embodiments of the present disclosure, as shown in FIGS. 3 to 7, the orthographic projection of the first refractive index film layer 180 in the first non-bending area NWB1 on the base substrate 100 has a sixth boundary S6 close to the bending area WB. The sixth boundary S6 can be set on the side of the third boundary S3 away from the display area AA. Exemplarily, there is a fourth distance d4 between the sixth boundary S6 and the third boundary S3. In this way, the first refractive index film layer 180 can completely surround the touch insulating layer 170 in the first non-bending area NWB1 as much as possible. Exemplarily, the fourth distance d4 may be no less than 10 μm.

In some embodiments of the present disclosure, as shown in FIG. 3 to FIG. 5 and FIG. 7, the orthographic projection of the first refractive index film layer 180 on the base substrate 100 covers the non-display area BB, the second non-bending area NWB2 and a portion of the bending area WB. Since the material of the first refractive index film layer 180 has good ductility, no cracks will occur when the base substrate 100 is bent. Therefore, the first refractive index film layer 180 covering a portion of the bending area WB will not cause corrosion of the signal line.

Exemplarily, as shown in FIGS. 3 to 5 and 7, the second distance d2 is not less than 5 μm. The distance between the sixth boundary S6 and the second boundary S2 is not less than 5 μm.

In some embodiments of the present disclosure, as shown in FIG. 6, the orthographic projection of the first refractive index film layer 180 on the base substrate 100 is disposed in the first non-bending area NWB1 and the second non-bending area NWB2.

Exemplarily, as shown in FIG. 6, the second distance d2 is not less than 100 μm, and the distance between the sixth boundary S6 and the second boundary S2 is not less than 90 μm.

In some embodiments of the present disclosure, as shown in FIGS. 3 to 7, the orthographic projection of the first refractive index film layer 180 in the second non-bending area NWB2 on the base substrate 100 has a seventh boundary S7 close to the bending area WB. There is a fifth distance d5 between the seventh boundary S7 and the fourth boundary S4. In this way, the first refractive index film layer 180 can completely surround the touch insulating layer 170 in the second non-bending area NWB2 as much as possible. Exemplarily, the fifth distance d5 may be no less than 10 μm.

Exemplarily, the fourth distance d4 and the fifth distance d5 may be set to be equal, so that the first refractive index film layer 180 on both sides of the bending area WB is at the same distance from the bending area WB, thereby achieving a symmetrical arrangement.

Multiple signal lines in the first non-bending area NWB1 of the base substrate 100 need to pass through the bending area WB to enter the second non-bending area NWB2, and then be connected to the driving chip through bonding in the second non-bending area NWB2, so that the driving chip inputs corresponding signals to these signal lines to control the display panel to display the picture.

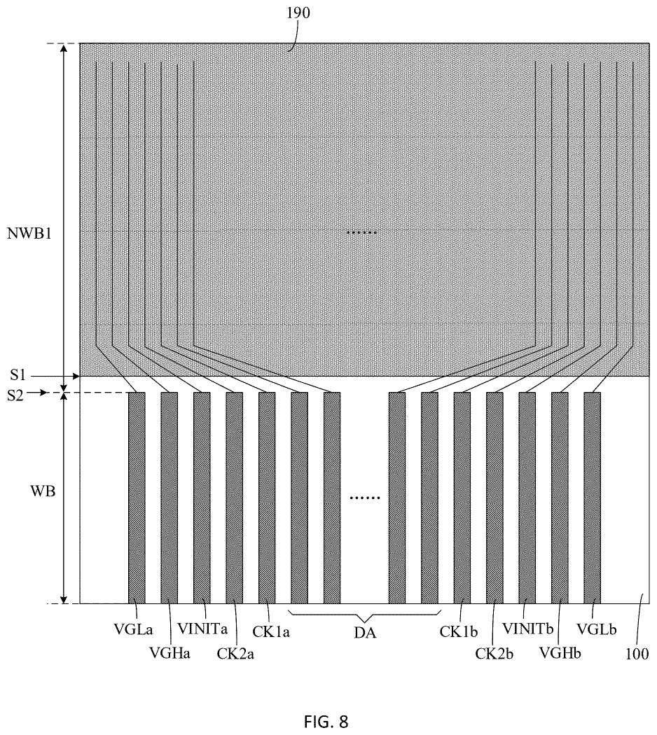

Exemplarily, as shown in FIG. 8, in the bending area WB and the non-bending area, all the data lines are arranged in the middle region of the base substrate 100. The clock signal lines (such as CK1a, CK2a, CK1b, CK2b), initialization signal lines (such as VINITa, VINITb), high voltage signal lines (such as VGHa, VGHb) and low voltage signal lines (such as VGLa, VGLb) are arranged in sequence on both sides of the data lines DA, so that the signal lines are also in a symmetrical arrangement. That is to say, the orthographic projection of the region where all the data lines DA are located on the base substrate 100 is set in the middle region of the base substrate 100. On both sides of the orthographic projection of the region where the data lines DA are located on the substrate 100, the orthographic projection of the region where the clock signal lines (such as CK1a, CK2a and CK1b, CK2b) are located on the substrate 100, the orthographic projection of the region where the initialization signal lines (such as VINITa, VINITb) are located on the substrate 100, the orthographic projection of the region where the high voltage signal lines (such as VGHa, VGHb) are located on the substrate 100 and the orthographic projection of the region where the low voltage signal lines (such as VGLa, VGLb) are located on the substrate 100 can be arranged in sequence.

Exemplarily, in combination with FIG. 3 and FIG. 8, a first distance d1 is between the first boundary S1 of the orthographic projection of the second refractive index film layer 190 on the base substrate 100 and the second boundary S2 of the bending area WB, which can prevent cracks in the second refractive index film layer 190, thereby reducing the corrosion and disconnection of the low voltage signal line and avoiding a black screen.

In order to further reduce the risk of low voltage signal lines being corroded and broken, as shown in FIG. 9, in the bending area WB, the orthographic projection of the region where the low voltage signal lines (such as VGLa, VGLb) are located on the base substrate 100 can be set between the orthographic projection of the region where the multiple data lines DA are located on the base substrate 100 and the edge of the base substrate 100. In this way, the region where the low voltage signal lines (such as VGLa and VGLb) are located is moved inward, away from the edge of the base substrate 100, and further, other signal lines are used to help block water and oxygen.

Exemplarily, as shown in FIG. 9, in the bending area WB, in the row direction of the pixel unit, a spacing distance H1a is between the orthographic projection of the region where the low voltage signal line VGLa is located on the base substrate 100 and the edge of the base substrate 100. The present disclosure does not limit the specific value of H1a. Exemplarily, 832 μm<H1a≤2000 μm. For example, H1a can be selected from 850 μm, 900 μm, 1000 μm, 1100 μm, 1500 μm, 1800 μm, 2000 μm, etc.

Exemplarily, as shown in FIG. 9, in the bending area WB, in the row direction of the pixel unit, a spacing distance H1b is between the orthographic projection of the region where the low voltage signal line VGLb is located on the base substrate 100 and the edge of the base substrate 100. The present disclosure does not limit the specific value of H1b. Exemplarily, 832 μm<H1b≤2000 μm. For example, H1b can be selected from 850 μm, 900 μm, 1000 μm, 1100 μm, 1500 μm, 1800 μm, 2000 μm, etc.

Exemplarily, H1a and H1b may be made equal to achieve a symmetrical arrangement.

In some examples, in the bending area, the orthographic projection of the region where the low voltage signal line is located on the base substrate can be set between the orthographic projection of the region where the multiple data lines are located on the base substrate and the orthographic projection of the region where the clock signal line is located on the substrate. For example, as shown in FIG. 9, the orthographic projection of the region where the low voltage signal line VGLa is located on the base substrate 100 is disposed between the orthographic projection of the region where the data lines DA are located on the substrate 100 and the orthographic projection of the region where the clock signal lines CK1a and CK2a are located on the substrate 100. The orthographic projection of the region where the low voltage signal line VGLb is located on the base substrate 100 is disposed between the orthographic projection of the region where the data lines DA are located on the base substrate 100 and the orthographic projections of the region where the clock signal lines CK1b and CK2b are located on the base substrate 100.

In some other examples, in the bending area, the orthographic projection of the region where the low voltage signal line is located on the substrate can be set between the orthographic projection of the region where the clock signal line is located on the substrate and the orthographic projection of the region where the initialization signal line is located on the substrate.

In some other examples, in the bending area, the orthographic projection of the region where the low voltage signal line is located on the substrate can be set between the orthographic projection of the region where the initialization signal line is located on the substrate and the orthographic projection of the region where the high voltage signal line is located on the substrate.

In some embodiments of the present disclosure, the display panel further includes: at least one dummy signal line disposed between the plurality of signal lines and an edge of the base substrate. Based on this, one or more dummy signal lines are designed to block water and oxygen to prevent reliability corrosion. It is understandable that the dummy signal line is a line that does not input any signal and is a line in a floating state.

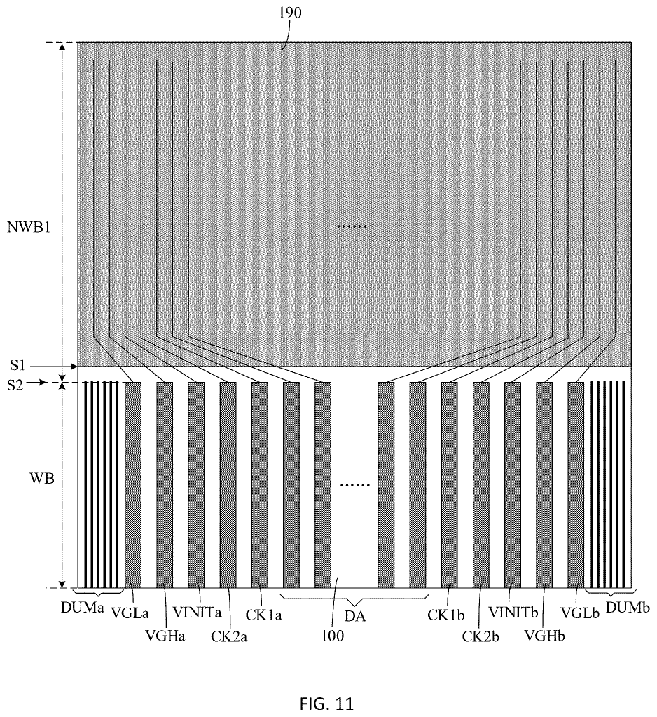

Exemplarily, as shown in FIG. 11, in the bending area WB, six dummy signal lines DUMa are set between the orthographic projection of the region where the low voltage signal line VGLa is located on the base substrate 100 and the edge of the base substrate 100. Six dummy signal lines DUMb are set between the orthographic projection of the region where the low voltage signal line VGLb is located on the base substrate 100 and the edge of the base substrate 100. That is, the number of dummy signal lines on the left and right sides is the same, achieving a symmetrical arrangement. Of course, the number of dummy signal lines on the left and right sides may also be different, which is not limited here.

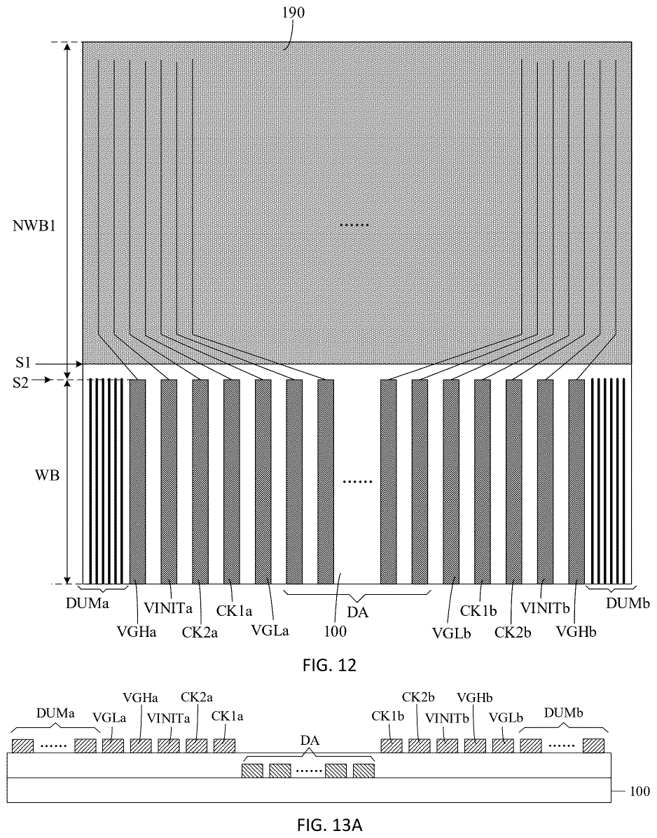

Exemplarily, as shown in FIG. 12, in the bending area WB, six dummy signal lines DUMa are set between the orthographic projection of the region where the high voltage signal line VGHa is located on the base substrate 100 and the edge of the base substrate 100, and six dummy signal lines DUMb are set between the orthographic projection of the region where the high voltage signal line VGHb is located on the base substrate 100 and the edge of the base substrate 100. That is, the number of dummy signal lines on the left and right sides is the same, achieving a symmetrical arrangement.

FIG. 11 and FIG. 12 are merely illustrative of the example of setting 6 dummy signal lines on the left and right sides respectively. In practical applications, the number of dummy signal lines can be set to 1, 2, 4, 8, 10, 15 or 20, and the present disclosure does not limit the number of dummy signal lines.

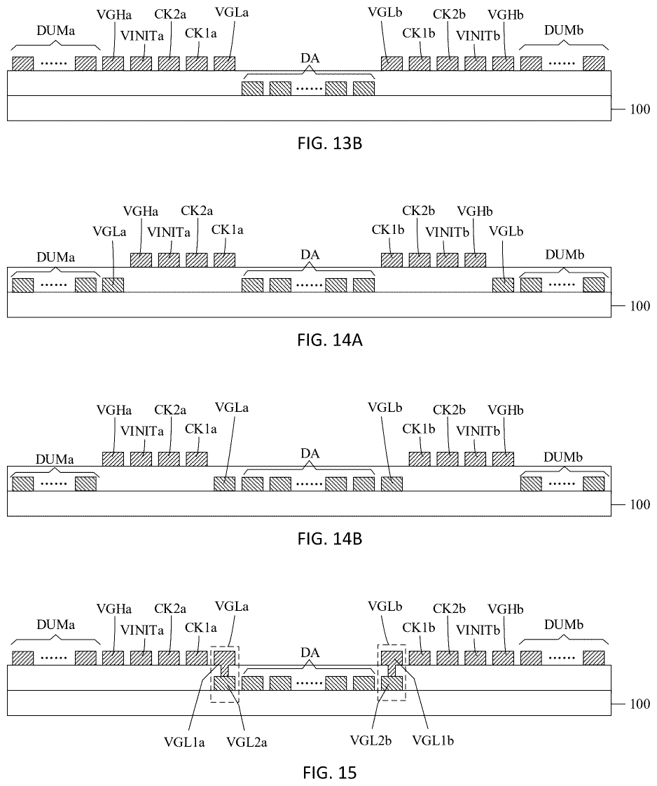

In some examples, as shown in FIGS. 13A and 13B, in the bending area WB, multiple data lines DA can be set in the first conductive layer, and low voltage signal lines VGLa, VGLb, initialization signal lines VINITa, VINITb, multiple clock signal lines CK1a, CK2a and CK1b, CK2b and high voltage signal lines VGHa, VGHb can be set in the second conductive layer.

In some other examples, as shown in FIG. 14A and FIG. 14B, in the bending area WB, a plurality of data lines DA and low voltage signal lines VGLa, VGLb may be disposed in the first conductive layer, which can further reduce the risk of the low voltage signal lines being corroded and broken. Furthermore, the initialized signal lines VINITa and VINITb, the plurality of clock signal lines CK1a and CK2a, CK1b and CK2b, and the high voltage signal lines VGHa and VGHb are provided in the second conductive layer.

In some further examples, in the bending area, the low voltage signal line includes a first low voltage signal line and a second low voltage signal line connected to each other. Multiple data lines and the first low voltage signal line are arranged in the first conductive layer, and the second low voltage signal line, an initialization signal line, multiple clock signal lines and a high voltage signal line are arranged in the second conductive layer, which can further reduce the corrosion and disconnection of the low voltage signal line. Exemplarily, as shown in FIG. 15, the low voltage signal line VGLa includes a first low voltage signal line VGL1a and a second low voltage signal line VGL2a connected to each other. The low voltage signal line VGLb includes a first low voltage signal line VGL1b and a second low voltage signal line VGL2b connected to each other. The first low voltage signal lines VGL1a and VGL1b are arranged in the first conductive layer, and the second low voltage signal lines VGL2a and VGL2b are arranged in the second conductive layer. The first low voltage signal line VGL1a and the second low voltage signal line VGL2a are connected to each other through a via hole penetrating the insulating layer, and the first low voltage signal line VGL1b and the second low voltage signal line VGL2b are connected to each other through a via hole penetrating the insulating layer.

When a dummy signal line is provided, the dummy signal line and the low voltage signal line may be provided on the same layer. For example, as shown in FIG. 13A and FIG. 13B, the low voltage signal lines VGLa, VGLb and the dummy signal lines DUMa, DUMb are all disposed in the second conductive layer. For example, as shown in FIG. 14A and FIG. 14B, the low voltage signal lines VGLa, VGLb and the dummy signal lines DUMa, DUMb are all disposed in the first conductive layer.

Exemplarily, the thickness of the layer where the low voltage signal line is located can be increased by 10% to 30% on the original set thickness A, so that the thickness of the layer where the low voltage signal line is located is A*110% to A*130%, thereby reducing the impedance of the signal line. Moreover, this solution can be implemented through the process without changing the mask.

Exemplarily, the thickness of the layer where the low voltage signal line is located can be A*110%, A*115%, A*120%, A*125%, or A*130%, which is not limited here. For example, A is 6000 Å. The thickness of the layer where the low voltage signal line is located is 7000 Å.

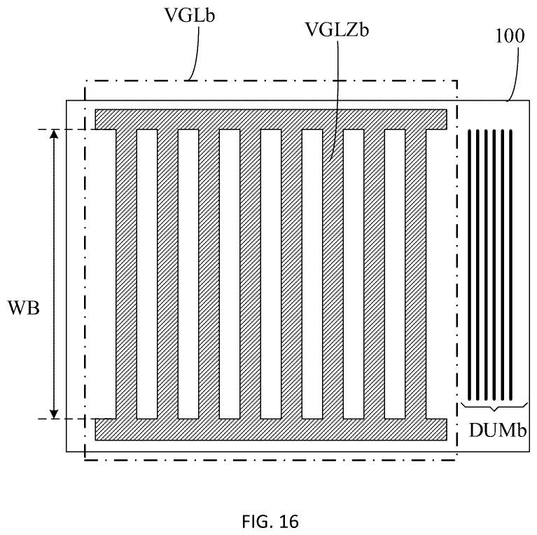

In some other examples, as shown in FIG. 16, the portion of the low voltage signal line VGLb in the bending area WB includes: a plurality of low voltage sub-signal lines VGLZb arranged at intervals from each other. Furthermore, one end of the plurality of low voltage sub-signal lines is connected to the low voltage signal line VGLb in the first non-bending area NWB1, and the other end of the plurality of low voltage sub-signal lines is connected to the low voltage signal line VGLb in the second non-bending area NWB2. It should be noted that FIG. 16 is only an example of a low voltage signal line VGLb and 8 low voltage sub-signal lines VGLZb. The specific value of the low voltage sub-signal line VGLZb can be determined according to the needs of actual applications. Furthermore, the low voltage signal line VGLa can be configured similarly, which will not be described in detail here.

Based on the same disclosed concept, embodiments of the present disclosure further provide a display device, including the above-mentioned display panel provided by embodiments of the present disclosure. The principle of solving the problem by the display device is similar to that of the aforementioned display panel, so the implementation of the display device can refer to the implementation of the aforementioned display panel, and the repeated parts will not be repeated here.

In implementations, in embodiments of the present disclosure, the display device may be: a mobile phone, a tablet computer, a television, a monitor, a laptop computer, a digital photo frame, a navigator, or any other product or component with a display function. Other essential components of the display device should be understood by those skilled in the art and will not be described in detail herein and should not be construed as limiting the present disclosure.

Although preferred embodiments of the present disclosure have been described, additional changes and modifications may be made to these embodiments once those skilled in the art are aware of the basic inventive concepts. Therefore, it is intended that the appended claims be interpreted as including the preferred embodiment as well as all changes and modifications that fall within the scope of the present disclosure.

Obviously, those skilled in the art can make various changes and modifications to the embodiments of the present disclosure without departing from the spirit and scope of the embodiments of the present disclosure. Thus, if these modifications and variations of the embodiments of the present disclosure fall within the scope of the claims of the present disclosure and their equivalents, the present disclosure is also intended to include these modifications and variations.

1.-30. (canceled)

31. A display panel, comprising:
a base substrate, comprising:
a bending area, and
a non-bending area;
wherein the non-bending area comprises a display area comprising a plurality of sub-pixels;
a first refractive index film layer on the base substrate, wherein the first refractive index film layer is disposed in the display area, the first refractive index film layer is provided with a plurality of openings, and the plurality of openings are disposed correspondingly to the plurality of sub-pixels;
a second refractive index film layer on a side of the first refractive index film layer away from the base substrate, wherein the second refractive index film layer covers the first refractive index film layer in the display area and fills the plurality of openings;
wherein a refractive index of the second refractive index film layer is greater than a refractive index of the first refractive index film layer; an orthographic projection of the second refractive index film layer on the base substrate does not overlap with the bending area, the orthographic projection of the second refractive index film layer on the base substrate has a first boundary close to the bending area, the bending area has a second boundary close to the second refractive index film layer, and a first distance between the first boundary and the second boundary is greater than 0.

32. The display panel according to claim 31, wherein the non-bending area comprises:
a first non-bending area, and
a second non-bending area,
wherein the first non-bending area and the second non-bending area are arranged on both sides of the bending area;
the first non-bending area comprises the display area, the second refractive index film layer is disposed in the first non-bending area, and the orthographic projection of the second refractive index film layer on the base substrate covers the display area.

33. The display panel according to claim 32, wherein the first boundary of the orthographic projection of the second refractive index film layer on the base substrate is aligned with a boundary of the display area close to the bending area.

34. The display panel according to claim 32, wherein the first non-bending area further comprises:
a non-display area between the display area and the bending area;
wherein the orthographic projection of the second refractive index film layer on the base substrate further covers a portion of the non-display area.

35. The display panel according to claim 34, wherein the first non-bending area further comprises:
at least two blocking dams surrounding the display area;
wherein the orthographic projection of the second refractive index film layer on the base substrate covers orthographic projections of the at least two blocking dams on the base substrate; or,
the orthographic projection of the second refractive index film layer on the base substrate does not overlap with a side edge of at least one blocking dam close to the bending area, and the orthographic projection of the second refractive index film layer on the base substrate further covers orthographic projections of remaining side edges of the at least two blocking dams on the base substrate.

36. The display panel according to claim 35, wherein the at least two blocking dams comprises:
a first blocking dam, and
a second blocking dam;
wherein the first blocking dam is arranged to surround the display area, and the second blocking dam is annularly arranged at a periphery of the first blocking dam;
the orthographic projection of the second refractive index film layer on the base substrate does not overlap with an orthographic projection of a side edge of the second blocking dam close to the bending area on the base substrate, and the orthographic projection of the second refractive index film layer on the base substrate further covers an orthographic projection of the first blocking dam and a remaining side edge of the second blocking dam on the base substrate.

37. The display panel according to claim 34, wherein the non-display area is further provided with the first refractive index film layer;
in the non-display area, an orthographic projection of the first refractive index film layer on the base substrate covers the orthographic projection of the second refractive index film layer on the base substrate.

38. The display panel according to claim 32, wherein the display panel further comprises:
a touch insulating layer between the first refractive index film layer and the base substrate, wherein the touch insulating layer is disposed in the first non-bending area and the second non-bending area;
wherein an orthographic projection of the touch insulating layer in the first non-bending area on the base substrate has a third boundary close to the bending area, a second distance is between the third boundary and the second boundary, and the second distance is not greater than the first distance.

39. The display panel according to claim 38, wherein the first non-bending area further comprises:
at least two blocking dams surrounding the display area;
wherein the orthographic projection of the touch insulating layer in the first non-bending area on the base substrate covers orthographic projections of the at least two blocking dams on the base substrate.

40. The display panel according to claim 38, wherein an orthographic projection of the touch insulating layer in the second non-bending area on the base substrate has a fourth boundary close to the bending area, the bending area has a fifth boundary close to the second non-bending area, a third distance is between the fourth boundary and the fifth boundary, and the third distance is not greater than the first distance.

41. The display panel according to claim 40, wherein the third distance is equal to the second distance.

42. The display panel according to claim 38, wherein in the non-display area, an orthographic projection of the first refractive index film layer on the base substrate covers the orthographic projection of the touch insulating layer on the base substrate.

43. The display panel according to claim 42, wherein:
the orthographic projection of the first refractive index film layer on the base substrate further covers the non-display area and a portion of the bending area.

44. The display panel according to claim 42, wherein:
an orthographic projection of the first refractive index film layer in the first non-bending area on the base substrate has a sixth boundary close to the bending area, a fourth distance is between the sixth boundary and the third boundary, and the fourth distance is not less than 10 μm; and/or
an orthographic projection of the first refractive index film layer in the second non-bending area on the base substrate has a seventh boundary close to the bending area, a fifth distance is between the seventh boundary and the fourth boundary, and the fifth distance is not less than 10 μm.

45. The display panel according to claim 44, wherein the fourth distance is equal to the fifth distance.

46. The display panel according to claim 31, further comprising:
a plurality of signal lines;
wherein the plurality of signal lines comprises:
a plurality of data lines, and
a low voltage signal line;
wherein in the bending area, an orthographic projection of a region where the low voltage signal line is located on the base substrate is arranged between an orthographic projection of a region where the plurality of data lines are located on the base substrate and an edge of the base substrate.

47. The display panel according to claim 46, wherein the plurality of signal lines further comprise:
an initialization signal line,
a plurality of clock signal lines, and
a high voltage signal line;
wherein in the bending area, the orthographic projection of the region where the low voltage signal line is located on the base substrate is arranged between two adjacent orthographic projections among the orthographic projection of the region where the plurality of data lines are located on the base substrate, an orthographic projection of a region where the initialization signal line is located on the base substrate, an orthographic projection of a region where the plurality of clock signal lines are located on the base substrate, and an orthographic projection of a region where the high voltage signal line is located on the base substrate.

48. The display panel according to claim 46, wherein:
in the bending area, the plurality of data lines and the low voltage signal line are arranged in a first conductive layer, and the initialization signal line, the plurality of clock signal lines and the high voltage signal line are arranged in a second conductive layer; or
in the bending area, the plurality of data lines are arranged in a first conductive layer, and the low voltage signal line, the initialization signal line, the plurality of clock signal lines and the high voltage signal line are arranged in a second conductive layer; or
in the bending area, the low voltage signal line comprises a first low voltage signal line and a second low voltage signal line connected to each other; the plurality of data lines and the first low voltage signal line are arranged in a first conductive layer, and the second low voltage signal line, the initialization signal line, the plurality of clock signal lines and the high voltage signal line are arranged in a second conductive layer;
wherein the first conductive layer is disposed between the second conductive layer and the base substrate, and an insulating layer is disposed between the first conductive layer and the second conductive layer.

49. A display panel, comprising:
a base substrate, comprising:
a bending area, and
a first non-bending area;
wherein the first non-bending area comprises a display area comprising a plurality of sub-pixels;
a first refractive index film layer on the base substrate, wherein the first refractive index film layer is disposed in the display area, the first refractive index film layer is provided with a plurality of openings, and the plurality of openings are disposed correspondingly to the plurality of sub-pixels;
a second refractive index film layer on a side of the first refractive index film layer away from the base substrate, wherein the second refractive index film layer covers the first refractive index film layer in the display area and fills the plurality of openings; wherein a refractive index of the second refractive index film layer is greater than a refractive index of the first refractive index film layer; and an orthographic projection of the second refractive index film layer on the base substrate does not overlap with the bending area;
a touch insulating layer between the first refractive index film layer and the base substrate;
wherein the orthographic projection of the second refractive index film layer on the base substrate has a first boundary close to the bending area, an orthographic projection of the touch insulating layer in the first non-bending area on the base substrate has a third boundary close to the bending area, and an orthographic projection of the first refractive index film layer in the first non-bending area on the base substrate has a sixth boundary close to the bending area, the third boundary is on a side of the first boundary away from the display area, and the sixth boundary is on a side of the third boundary away from the display area.

50. The display panel according to claim 49, wherein the bending area has a second boundary close to the second refractive index film layer, and a first distance between the first boundary and the second boundary is greater than 0;
a second distance is between the third boundary and the second boundary, and the second distance is not greater than the first distance.
